(19) United States
(12) Patent Application Publication
(10) Pub. No.: US 2025/0072116 A1
(43) Pub. Date: Feb. 27, 2025

(54) NANOSHEET BASED EXTENDED-GATE DEVICE INTEGRATION

(71) Applicant: International Business Machines Corporation, Armonk, NY (US)

(72) Inventors: Juntao Li, Cohoes, NY (US); Ruilong Xie, Niskayuna, NY (US); Julien Frougier, Albany, NY (US); Min Gyu Sung, Latham, NY (US); Chanro Park, Clifton Park, NY (US)

(21) Appl. No.: 18/452,682

(22) Filed: Aug. 21, 2023

(51) Int. Cl. H01L 27/12; H01L 21/8234; H01L 21/84

(52) U.S. Cl. CPC H01L 27/1207; H01L 21/823462; H01L 21/823468; H01L 21/84

(57) ABSTRACT

A semiconductor device comprises a first nanosheet transistor disposed on a semiconductor substrate, the first nanosheet transistor comprising a plurality of first gate structures, and a second nanosheet transistor disposed on the semiconductor substrate, the second nanosheet transistor comprising a plurality of second gate structures. Respective stacked spacer structures are disposed on respective sides of respective ones of the plurality of second gate structures, wherein each of the respective stacked spacer structures comprises a first spacer and a second spacer. Respective ones of the plurality of first gate structures comprise a first nanosheet gate portion and a gate dielectric layer around the first nanosheet gate portion. The respective ones of the plurality of second gate structures comprise a second nanosheet gate portion and at least two gate dielectric layers around the second nanosheet gate portion.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming extended-gate (EG) nanosheet transistors.

In one embodiment, a semiconductor device comprises a first nanosheet transistor disposed on a semiconductor substrate, the first nanosheet transistor comprising a plurality of first gate structures, and a second nanosheet transistor disposed on the semiconductor substrate, the second nanosheet transistor comprising a plurality of second gate structures. Respective stacked spacer structures are disposed on respective sides of respective ones of the plurality of second gate structures, wherein each of the respective stacked spacer structures comprises a first spacer and a second spacer. Respective ones of the plurality of first gate structures comprise a first nanosheet gate portion and a gate dielectric layer around the first nanosheet gate portion. The respective ones of the plurality of second gate structures comprise a second nanosheet gate portion and at least two gate dielectric layers around the second nanosheet gate portion.

In another embodiment, a semiconductor device comprises a first nanosheet structure comprising a first plurality of gate structures alternately stacked with a first plurality of channel layers, and a second nanosheet structure comprising a second plurality of gate structures alternately stacked with a second plurality of channel layers. Respective stacked spacer structures are disposed on respective sides of the respective ones of the second plurality of gate structures, wherein each of the respective stacked spacer structures comprises a first spacer and a second spacer. Respective ones of the first plurality of gate structures comprise a first nanosheet gate portion and a gate dielectric layer around the first nanosheet gate portion. Respective ones of the second plurality of gate structures comprise a second nanosheet gate portion and at least two gate dielectric layers around the second nanosheet gate portion.

In another embodiment, a semiconductor device comprises a first nanosheet transistor and a second nanosheet transistor disposed on a semiconductor substrate. The first nanosheet transistor comprises a first plurality of stacked gate portions, a gate dielectric layer around respective ones of the first plurality of stacked gate portions and a first source/drain region disposed on a side of the first plurality of stacked gate portions. The second nanosheet transistor comprises a second plurality of stacked gate portions, at least two gate dielectric layers around respective ones of the second plurality of stacked gate portions and a second source/drain region disposed on a side of the second plurality of stacked gate portions. Respective stacked spacer structures are disposed on respective sides of the respective ones of the second plurality of stacked gate portions between the second source/drain region and the respective ones of the second plurality of stacked gate portions, wherein each of the respective stacked spacer structures comprises a first spacer and a second spacer.

These and other features and advantages of embodiments described herein will become more apparent from the accompanying drawings and the following detailed description.

### BRIEF DESCRIPTION OF THE DRAWINGS

FIG. 1A depicts a top view of a semiconductor structure with line X1 on which the cross-sectional views of FIGS. 2A, 3A, 4A, 5A, 6A, 7A, 8A, 9A, 10A, 11A, 12A, 13A, 14A, 15A, 16A and 17A are based, according to an embodiment of the invention.

FIG. 1B depicts a top view of the semiconductor structure with line X2 on which the cross-sectional views of FIGS. 2B, 3B, 4B, 5B, 6B, 7B, 8B, 9B, 10B, 11B, 12B, 13B, 14B, 15B, 16B and 17B are based, according to an embodiment of the invention.

FIG. 2A depicts a first cross-sectional view corresponding to the line X1 in FIG. 1A illustrating semiconductor nanosheet layers in a standard-gate (SG) device region, according to an embodiment of the invention.

FIG. 2B depicts a second cross-sectional view corresponding to the line X2 in FIG. 1B illustrating semiconductor nanosheet layers in an EG device region, according to an embodiment of the invention.

FIG. 3A depicts a first cross-sectional view corresponding to the line X1 in FIG. 1A following hardmask formation on the semiconductor nanosheet layers in the SG device region, according to an embodiment of the invention.

FIG. 3B depicts a second cross-sectional view corresponding to the line X2 in FIG. 1B illustrating semiconductor nanosheet layer removal from the EG device region, according to an embodiment of the invention.

FIG. 4A depicts a first cross-sectional view corresponding to the line X1 in FIG. 1A illustrating the hardmask on the semiconductor nanosheet layers in the SG device region, according to an embodiment of the invention.

FIG. 4B depicts a second cross-sectional view corresponding to the line X2 in FIG. 1B following formation of new semiconductor nanosheet layers in the EG device region, according to an embodiment of the invention.

FIG. 5A depicts a first cross-sectional view corresponding to the line X1 in FIG. 1A following hardmask removal from the semiconductor nanosheet layers in the SG device region, according to an embodiment of the invention.

FIG. 5B depicts a second cross-sectional view corresponding to the line X2 in FIG. 1B illustrating the new semiconductor nanosheet layers in the EG device region, according to an embodiment of the invention.

FIG. 6A depicts a first cross-sectional view corresponding to the line X1 in FIG. 1A following dummy gate formation in the SG device region, according to an embodiment of the invention.

FIG. 6B depicts a second cross-sectional view corresponding to the line X2 in FIG. 1B following dummy gate formation in the EG device region, according to an embodiment of the invention.

FIG. 7A depicts a first cross-sectional view corresponding to the line X1 in FIG. 1A following selective removal of a sacrificial semiconductor layer in the SG device region, according to an embodiment of the invention.

FIG. 7B depicts a second cross-sectional view corresponding to the line X2 in FIG. 1B illustrating maintaining of the structure from FIG. 6B in the EG device region, according to an embodiment of the invention.

FIG. 8A depicts a first cross-sectional view corresponding to the line X1 in FIG. 1A following gate spacer formation and bottom dielectric insulator layer (BDI) formation in the SG device region, according to an embodiment of the invention.

FIG. 8B depicts a second cross-sectional view corresponding to the line X2 in FIG. 1B following gate spacer formation in the EG device region, according to an embodiment of the invention.

FIG. 9A depicts a first cross-sectional view corresponding to the line X1 in FIG. 1A following removal of portions of the semiconductor nanosheet layers in the SG device region, according to an embodiment of the invention.

FIG. 9B depicts a second cross-sectional view corresponding to the line X2 in FIG. 1B following removal of portions of the semiconductor nanosheet layers and recessing part of the semiconductor substrate in the EG device region, according to an embodiment of the invention.

FIG. 10A depicts a first cross-sectional view corresponding to the line X1 in FIG. 1A following lateral recessing of sacrificial semiconductor layers in the SG device region, according to an embodiment of the invention.

FIG. 10B depicts a second cross-sectional view corresponding to the line X2 in FIG. 1B following lateral recessing of sacrificial semiconductor layers in the EG device region, according to an embodiment of the invention.

FIG. 11A depicts a first cross-sectional view corresponding to the line X1 in FIG. 1A following deposition of inner spacer material in the SG device region, according to an embodiment of the invention.

FIG. 11B depicts a second cross-sectional view corresponding to the line X2 in FIG. 1B following deposition of inner spacer material in the EG device region, according to an embodiment of the invention.

FIG. 12A depicts a first cross-sectional view corresponding to the line X1 in FIG. 1A following etching back of inner spacer material to form inner spacers in the SG device region, according to an embodiment of the invention.

FIG. 12B depicts a second cross-sectional view corresponding to the line X2 in FIG. 1B following etching back of inner spacer material to form inner spacers in the EG device region, according to an embodiment of the invention.

FIG. 13A depicts a first cross-sectional view corresponding to the line X1 in FIG. 1A following epitaxial source/drain region formation in the SG device region, according to an embodiment of the invention.

FIG. 13B depicts a second cross-sectional view corresponding to the line X2 in FIG. 1B following epitaxial source/drain region formation in the EG device region, according to an embodiment of the invention.

FIG. 14A depicts a first cross-sectional view corresponding to the line X1 in FIG. 1A following inter-layer dielectric (ILD) layer formation and planarization in the SG device region, according to an embodiment of the invention.

FIG. 14B depicts a second cross-sectional view corresponding to the line X2 in FIG. 1B following inter-layer dielectric (ILD) layer formation and planarization in the EG device region, according to an embodiment of the invention.

FIG. 15A depicts a first cross-sectional view corresponding to the line X1 in FIG. 1A following dummy gate and sacrificial semiconductor layer removal in the SG device region, according to an embodiment of the invention.

FIG. 15B depicts a second cross-sectional view corresponding to the line X2 in FIG. 1B following dummy gate and sacrificial semiconductor layer removal in the EG device region, according to an embodiment of the invention.

FIG. 16A depicts a first cross-sectional view corresponding to the line X1 in FIG. 1A following semiconductor channel layer trimming in the SG device region, according to an embodiment of the invention.

FIG. 16B depicts a second cross-sectional view corresponding to the line X2 in FIG. 1B following semiconductor channel layer trimming and removal in the EG device region, according to an embodiment of the invention.

FIG. 17A depicts a first cross-sectional view corresponding to the line X1 in FIG. 1A following replacement metal gate (RMG) and gate dielectric formation in the SG device region, according to an embodiment of the invention.

FIG. 17B depicts a second cross-sectional view corresponding to the line X2 in FIG. 1B following RMG and gate dielectric formation in the EG device region, according to an embodiment of the invention.

### DETAILED DESCRIPTION

Illustrative embodiments of the invention may be described herein in the context of illustrative methods for forming EG nanosheet transistors, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheet channels may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

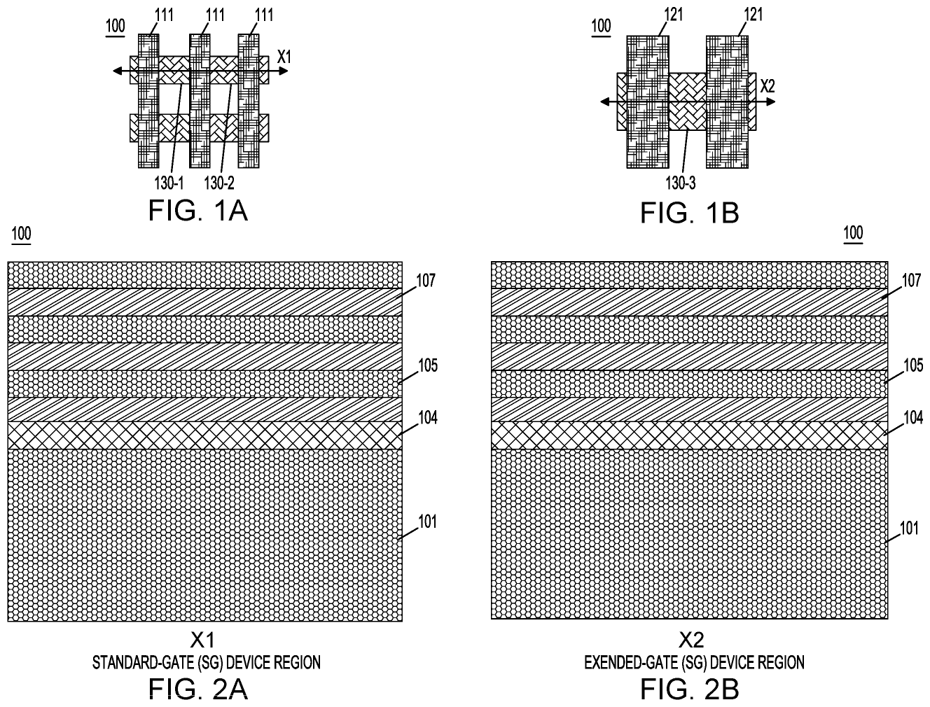

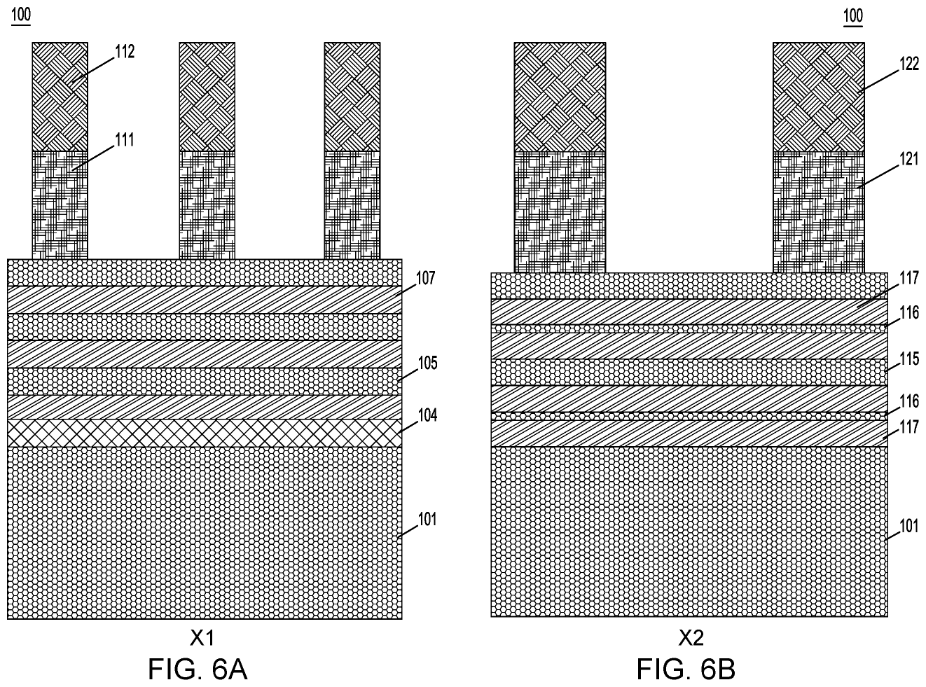

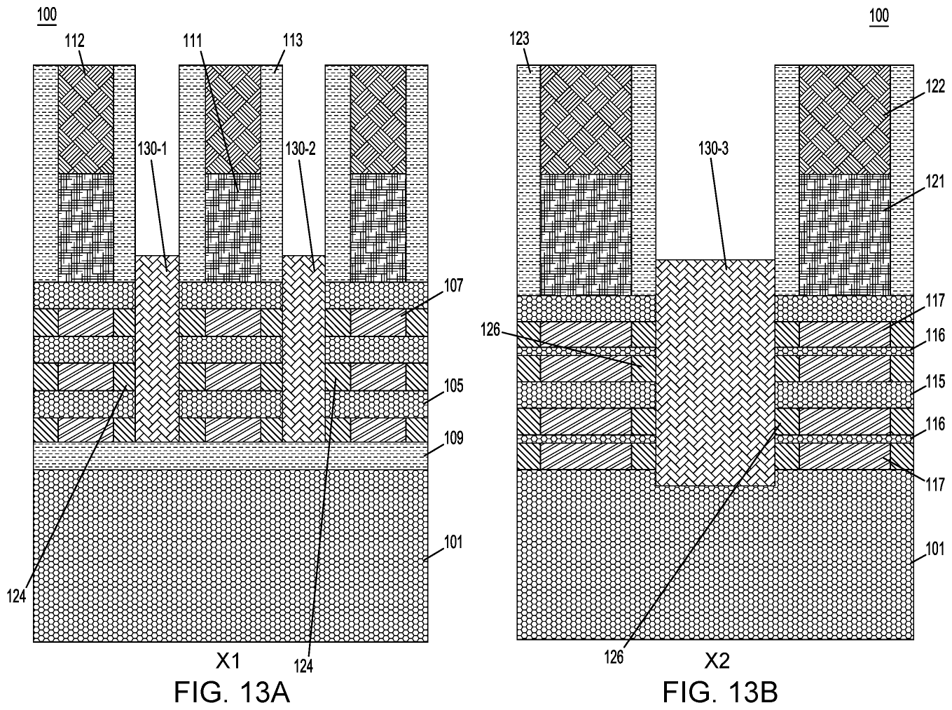

FIG. 1A depicts a top view of a semiconductor structure 100 with line X1 on which the cross-sectional views of FIGS. 2A, 3A, 4A, 5A, 6A, 7A, 8A, 9A, 10A, 11A, 12A, 13A, 14A, 15A, 16A and 17A are based, and FIG. 1B depicts a top view of the semiconductor structure 100 with line X2 on which the cross-sectional views of FIGS. 2B, 3B, 4B, 5B, 6B, 7B, 8B, 9B, 10B, 11B, 12B, 13B, 14B, 15B, 16B and 17B are based. FIGS. 1A and 1B illustrate dummy gate portions 111 and 121 and source/drain regions 130-1, 130-2 and 130-3 (collectively, “source/drain regions 130”), which are described in more detail herein in connection with, for example, FIGS. 6A, 6B, 13A and 13B.

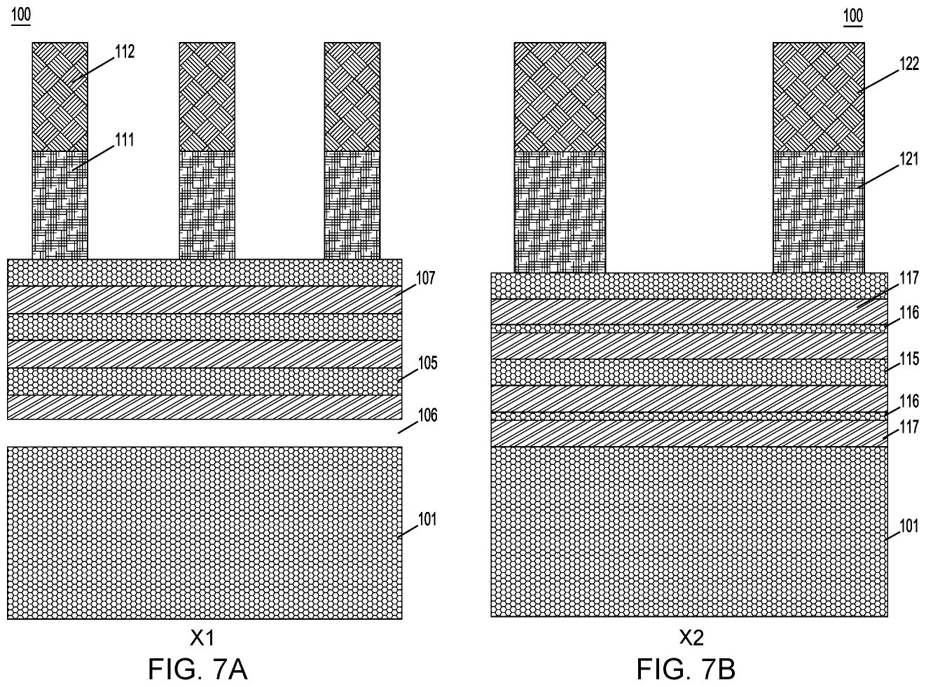

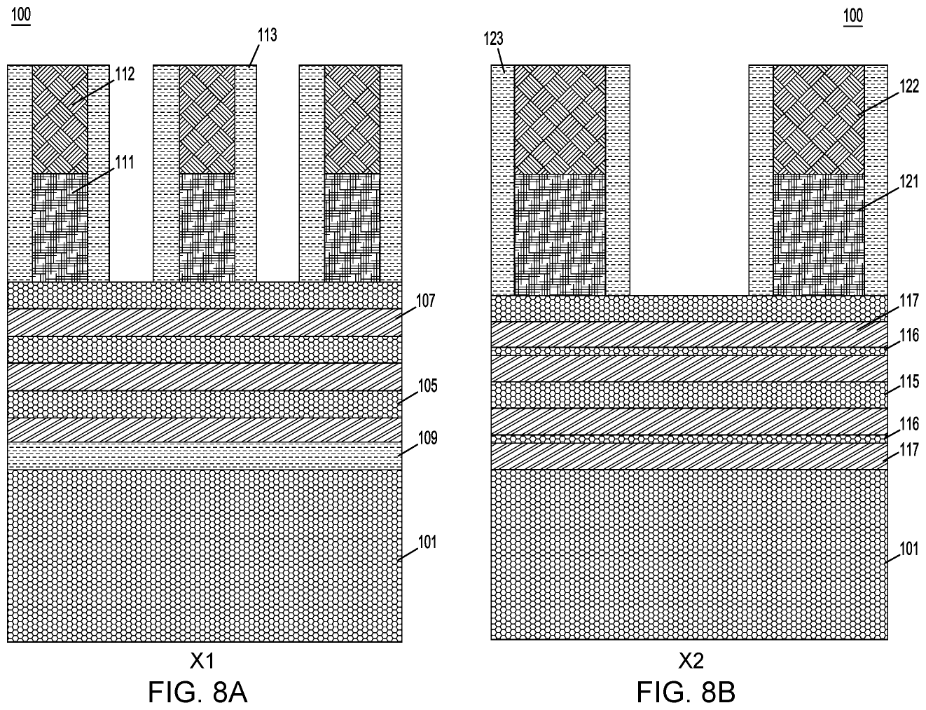

Referring to FIGS. 1A, 1B, 2A and 2B, a semiconductor structure 100 includes a stacked structure of sacrificial layers 107 and channel layers 105 in both SG and EG device regions. In an illustrative embodiment, the sacrificial layers 107 comprise silicon germanium (SiGe) and the channel layers 105 comprise silicon. In illustrative embodiments, the sacrificial layers 107 comprise a germanium concentration of about 30% (e.g., SiGe30), but the embodiments are not necessarily limited to SiGe30 for the sacrificial layers 107. The lowermost sacrificial layer is formed on an additional sacrificial layer 104 including, for example, SiGe with a different concentration of germanium than that of the sacrificial layers 107. For example, the additional sacrificial layer 104 has, but is not necessarily limited to, a germanium concentration of about 55% (e.g., SiGe55). As explained in more detail herein, the additional sacrificial layer 104 has a different concentration of germanium than the sacrificial layers 107 so that the additional sacrificial layer 104 can be selectively etched and removed with respect to sacrificial layers 107 when forming a bottom dielectric isolation (BDI) layer in the SG device region (see, e.g., FIG. 7A and FIG. 8A including BDI layer 109).

A semiconductor substrate 101 comprises semiconductor material including, but not limited to, silicon (Si), III-V, II-V compound semiconductor materials or other like semiconductor materials. In addition, multiple layers of the semiconductor materials can be used as the semiconductor material of the semiconductor substrate 101.

The sacrificial layers 107 and channel layers 105 are epitaxially grown in an alternating and stacked configuration on the additional sacrificial layer 104. A first sacrificial layer 107 is followed by a first channel layer 105 on the first sacrificial layer 107, which is followed by a second sacrificial layer 107 on the first channel layer 105, and so on. As can be understood, the sacrificial and channel layers 105 and 107 are epitaxially grown from their corresponding underlying semiconductor layers.

While three sacrificial layers 107 and three channel layers 105 are shown, the embodiments of the present invention are not necessarily limited to the shown number of sacrificial and channel layers 105 and 107, and there may be more or less layers in the same alternating configuration depending on design constraints. The sacrificial layers 107 in the SG device region, as described further herein, are eventually removed and replaced by gate structures.

Although SiGe is described as a sacrificial material for sacrificial layers 107, other materials can be used as long as the sacrificial layers 107 have the property of being able to be removed selectively compared to the material of the channel layers 105.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a thickness (e.g., vertical height in the cross-sectional views) of the sacrificial layers 107 can be in the range of about 6 nm to about 15 nm depending on the application of the device. Also, in a non-limiting illustrative embodiment, a thickness (e.g., vertical height in the cross-sectional views) of the channel layers 105 can be in the range of about 6 nm to about 15 nm depending on the desired process and application. In accordance with an embodiment of the present invention, each of the channel layers 105 has the same or substantially the same composition and size as each other, and each of the sacrificial layers 107 has the same or substantially the same composition and size as each other.

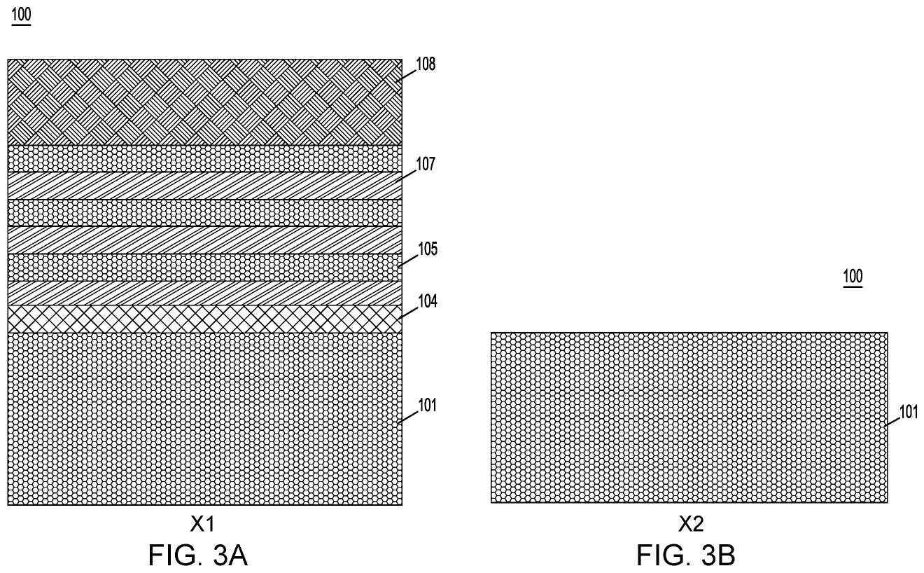

Referring to FIGS. 3A and 3B, a hardmask layer 108 is formed on the stacked configuration of the sacrificial layers 107 and channel layers 105 on the additional sacrificial layer 104 in the SG device region, but not on the stacked configuration of the sacrificial layers 107 and channel layers 105 on the additional sacrificial layer 104 in the EG device region. The hardmask layer 108 comprises, for example, a nitride such as silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), combinations thereof or other nitride material. As can be seen in FIG. 3B, the exposed stacked configuration comprising the sacrificial layers 107 and channel layers 105 on the additional sacrificial layer 104 in the EG device region is removed down to the semiconductor substrate 101. The removal can be performed using, for example, an anisotropic reactive ion etch (RIE) process comprising, for example, fluorine or chlorine-based gases.

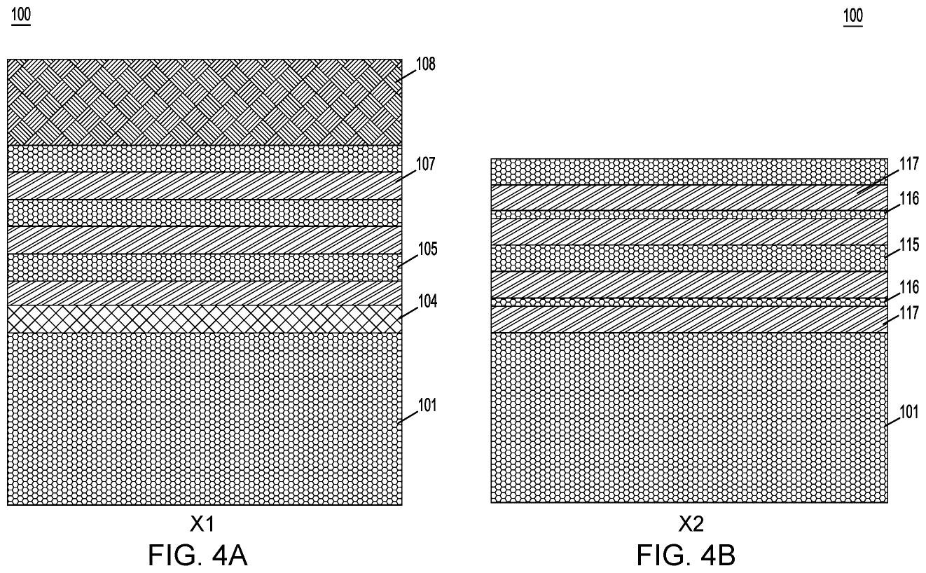

Referring to FIGS. 4A and 4B, while the hardmask layer 108 remains on the stacked configuration of the sacrificial layers 107 and channel layers 105 on the additional sacrificial layer 104 in the SG device region, new semiconductor nanosheet layers are epitaxially grown in the EG device region. As shown in FIG. 4B, in the EG device region, the semiconductor structure 100 includes a stacked structure of EG region sacrificial layers 117, semiconductor layers 116 and EG region channel layers 115 in the EG device region. In an illustrative embodiment, the EG region sacrificial layers 117 comprise the same or similar material as the sacrificial layers 107 (e.g., SiGe) and the EG region channel layers 115 and semiconductor layers 116 comprise the same or similar material as the channel layers 105 (e.g., silicon). The semiconductor layers 116 are thinner (e.g., have a smaller vertical height in the cross-sectional views) than the EG region channel layers 115. The EG region channel layers 115 and the EG region sacrificial layers 117 may have the same or similar thickness to those of the channel layers 105 and the sacrificial layers 107. A thickness (e.g., vertical height in the cross-sectional views) of the semiconductor layers 116 can be in the range of about 1 nm—about 5 nm depending on the application of the device. In illustrative embodiments, the EG region sacrificial layers 117 comprise a germanium concentration of about 30% (e.g., SiGe30), but the embodiments are not necessarily limited to SiGe30 for the EG region sacrificial layers 117. The lowermost EG region sacrificial layer 117 is formed on and contacts the semiconductor substrate 101, unlike the lowermost sacrificial layer 107, which is formed on and contacts the additional sacrificial layer 104.

A configuration is shown in which a first EG region sacrificial layer 117 is followed by a semiconductor layer 116, a second EG region sacrificial layer 117 and a first EG region channel layer 115. This pattern of an EG region sacrificial layer 117, a semiconductor layer 116, another EG region sacrificial layer 117 and an EG region channel layer 115 is repeated. As can be understood, the EG region sacrificial layers 117, semiconductor layers 116 and EG region channel layers 115 are epitaxially grown from their corresponding underlying semiconductor layers.

While the pattern in the EG device region repeats twice as shown, the embodiments of the present invention are not necessarily limited to the shown number of patterns. The EG region sacrificial layers 117 and middle portions of the semiconductor layers in the EG device region, as described further herein, are eventually removed and replaced by gate structures.

Although SiGe is described as a sacrificial material for the EG region sacrificial layers 117, other materials can be used as long as the EG region sacrificial layers 117 have the property of being able to be removed selectively compared to the material of the EG region channel layers 115 and the semiconductor layers 116.

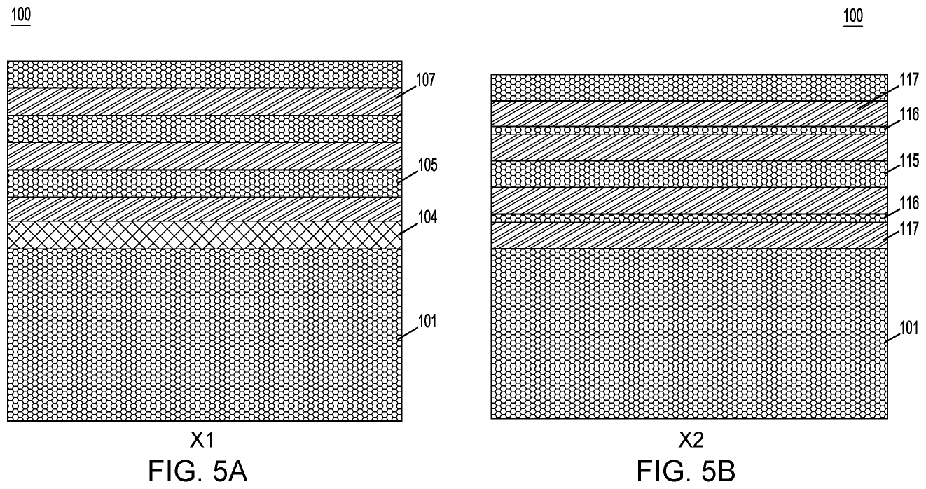

Referring to FIG. 5A, the hardmask layer 108 is removed. Although not shown in FIGS. 5A and 5B, in the SG device region portions of the nanosheet stacks comprising the sacrificial layers 107 and channel layers 105 are removed, portions of the additional sacrificial layer 104 are removed and portions of the semiconductor substrate 101 are recessed. In the EG device region, portions of the nanosheet stacks comprising the EG region sacrificial layers 117, semiconductor layers 116 and EG region channel layers 115 are removed and portions of the semiconductor substrate 101 are recessed. Isolation regions (e.g., shallow trench isolation (STI) regions) are formed between the remaining nanosheet stacks, and remaining portions of the additional sacrificial layer 104 and the semiconductor substrate 101. The dielectric material of the isolation regions may comprise, for example, SiN, SiON, SiCN, BN, SiBN, SiBCN, SiOCN and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

Referring to FIG. 6A, dummy gate portions 111 are formed on the uppermost channel layer 105 in the SG device region and, although not shown, around the stacked nanosheet configuration of the sacrificial layers 107 and channel layers 105. Referring to FIG. 6B, dummy gate portions 121 are formed on the uppermost EG region channel layer 115 in the EG device region and, although not shown, around the stacked nanosheet configuration of the EG region sacrificial layers 117, semiconductor layers 116 and EG region channel layers 115. The dummy gate portions 121 are wider (left to right direction in the cross-sectional views of FIGS. 6A and 6B) than the dummy gate portions 111. The dummy gate portions 111 and 121 include, but are not necessarily limited to, an amorphous silicon (a-Si) layer. The dummy gate portions 111 and 121 are deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer. Hardmask layers 112 are formed on the dummy gate portions 111, and hardmask layers 122 are formed on the dummy gate portions 121. The hardmask layers 112 and 122 comprise, for example, a nitride such as SiN, SiON, SiCN, BN, SiBN, SiBCN, SiOCN, combinations thereof or other nitride material.

Referring to FIG. 7A, the additional sacrificial layer 104 between the lowermost sacrificial layer 107 and semiconductor substrate 101 in the SG device region is removed using, for example, an aqueous solution containing ammonium hydroxide (NH₄OH) and hydrogen peroxide (H₂O₂) or a gas containing hydrogen chloride (HCl) to selectively etch the additional sacrificial layer 104 with respect to the semiconductor substrate 101, the sacrificial layers 107 and the channel layers 105. The selective etching removes the additional sacrificial layer 104 to form a vacant area 106 where the BDI layer 109 is formed.

Referring to FIG. 8A, in the SG device region, dielectric material is deposited in place of the additional sacrificial layer 104 using deposition techniques such as, for example, CVD, PECVD, RFCVD, PVD, ALD, MBD, PLD, and/or LSMCD, followed by an etch back to form the BDI layer 109 on the semiconductor substrate 101 in the vacant area 106 in place of the additional sacrificial layer 104. The BDI layer 109 may comprise, for example, silicon oxide (SiOₓ) (where x is for example, 2, 1.99 or 2.01), silicon oxycarbide (SiOC), SiN, SiON, SiCN, BN, SiBCN, SiOCN or some other dielectric. The BDI layer 109 is under a bottom surface of the lowermost sacrificial layer 107. As can be understood from FIGS. 7B and 8B, since there is no additional sacrificial layer in the EG device region, a BDI layer is not formed in the EG device region.

Referring to FIGS. 8A and 8B, in the SG device region, gate spacers 113 are formed on sides of the hardmask layers 112 and dummy gate portions 111, and in the EG device region, gate spacers 123 are formed on sides of the hardmask layers 122 and dummy gate portions 121. The gate spacers 113 and 123 are formed by one or more of the deposition techniques noted in connection with deposition of the dummy gate material. The spacer material can comprise for example, one or more dielectrics, including, but not necessarily limited to, SiN, SiON, SiOC, SiCN, BN, SiBN, SiBCN, SiOCN, SiOₓ, and combinations thereof. According to an embodiment, the BDI layer 109 and gate spacers 113 and 123 can be the same material or different materials. The gate spacers 113 and 123 can be formed by any suitable techniques such as deposition followed by directional etching. Deposition may include but is not limited to, ALD or CVD. Directional etching may include, but is not limited to, RIE.

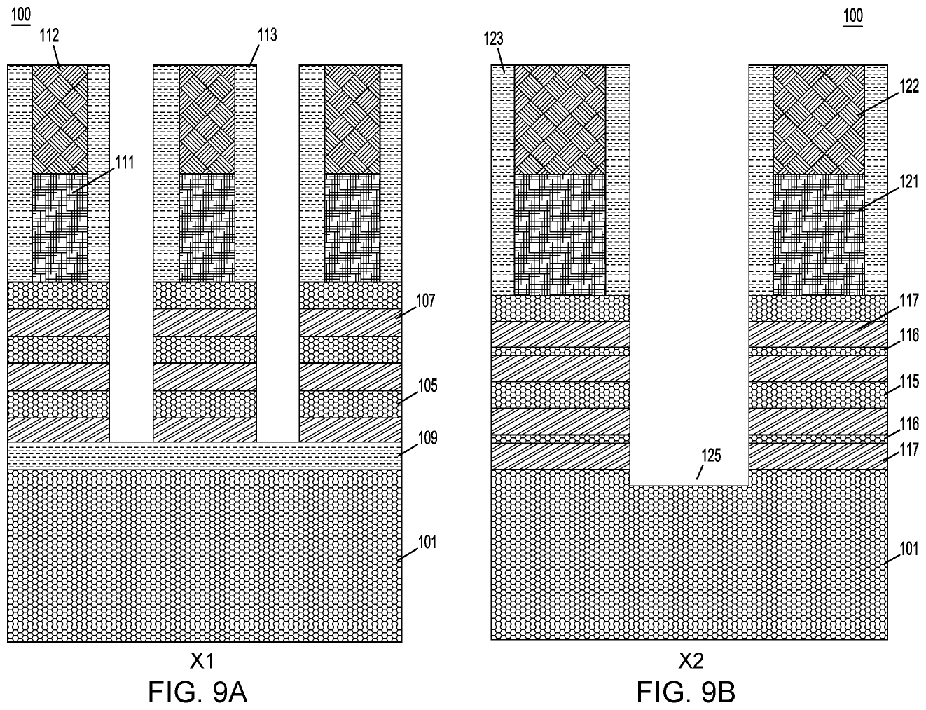

Referring to FIG. 9A, exposed portions of the stacked sacrificial layers 107 and channel layers 105 in the SG device region, which are not under the hardmask layers 112, gate spacers 113 and dummy gate portions 111, are removed using, for example, an etching process, such as RIE, where the hardmask layers 112, gate spacers 113 and dummy gate portions 111 are used as a mask. The portions of the stacked structures of sacrificial layers 107 and channel layers 105 under the hardmask layers 112, gate spacers 113 and under the dummy gate portions 111 remain after the etching process, and portions of the sacrificial layers 107 and channel layers 105 in areas that correspond to where source/drain regions will be formed are removed. The etching is stopped at the BDI layer 109. Portions of the top surface of the BDI layer 109 on sides of the stacked structures of sacrificial layers 107 and channel layers 105 are exposed.

Referring to FIG. 9B, exposed portions of the stacked EG region sacrificial layers 117, semiconductor layers 116 and EG region channel layers 115 in the EG device region, which are not under the hardmask layers 122, gate spacers 123 and dummy gate portions 121, are removed using, for example, an etching process, such as RIE, where the hardmask layers 122, gate spacers 123 and dummy gate portions 121 are used as a mask. The portions of the stacked structures of EG region sacrificial layers 117, semiconductor layers 116 and EG region channel layers 115 under the hardmask layers 122, gate spacers 123 and under the dummy gate portions 121 remain after the etching process, and portions of the EG region sacrificial layers 117, semiconductor layers 116 and EG region channel layers 115 in areas that correspond to where a source/drain region will be formed are removed. The etching exposes a portion of the top surface of the semiconductor substrate 101. Part of the semiconductor substrate 101 is removed to create a recessed portion 125 of the semiconductor substrate 101 in the EG device region.

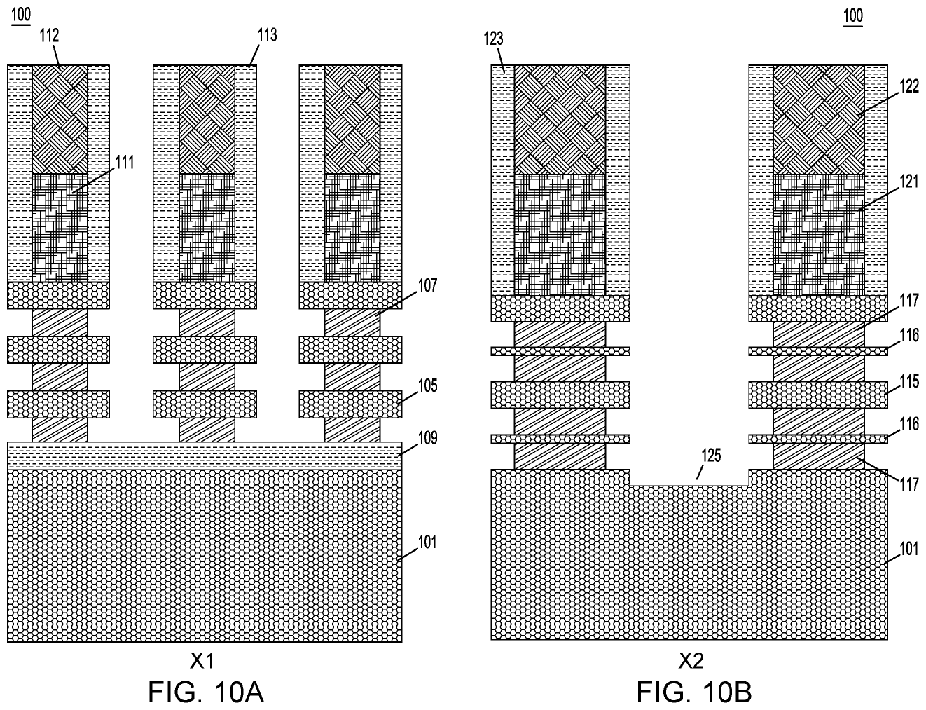

Referring to FIG. 10A, in the SG device region, due to, for example, germanium in the sacrificial layers 107, lateral etching of the sacrificial layers 107 can be performed selective to the channel layers 105, such that the side portions of the sacrificial layers 107 can be removed to create vacant areas to be filled in by inner spacers. Referring to FIG. 10B, in the EG device region, due to, for example, germanium in the EG region sacrificial layers 117, lateral etching of the EG region sacrificial layers 117 can be performed selective to the EG region channel layers 115 and semiconductor layers 116, such that the side portions of the EG region sacrificial layers 117 can be removed to create vacant areas to be filled in by inner spacers.

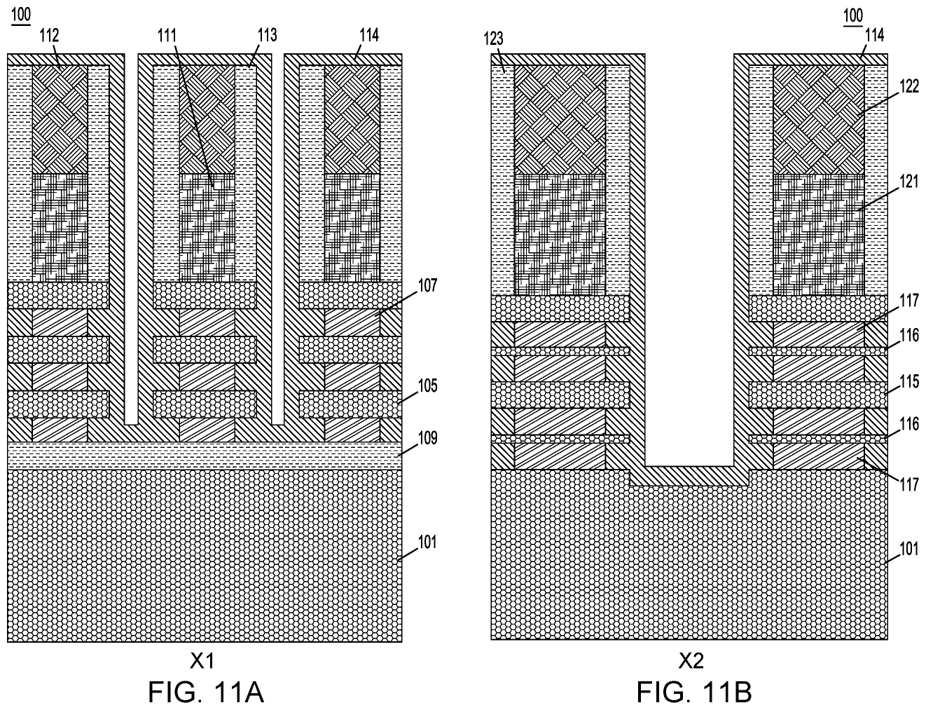

Referring to FIGS. 11A and 11B, inner spacer dielectric material 114 is deposited in the SG and EG device regions on exposed surfaces of the hardmask layers 112/122, gate spacers 113/123, sacrificial layers 107, EG region sacrificial layers 117, semiconductor layers 116, channel layers 105. EG region channel layers 115, BDI layer 109 and the semiconductor substrate 101. The inner spacer dielectric material 114 can comprise, but is not necessarily limited to, a nitride, such as, SiN, SiON, SiCN, BN, SiBN, SiBCN or SiOCN. The inner spacer dielectric material 114 can be formed by any suitable deposition techniques such as, but not necessarily limited to, ALD or CVD.

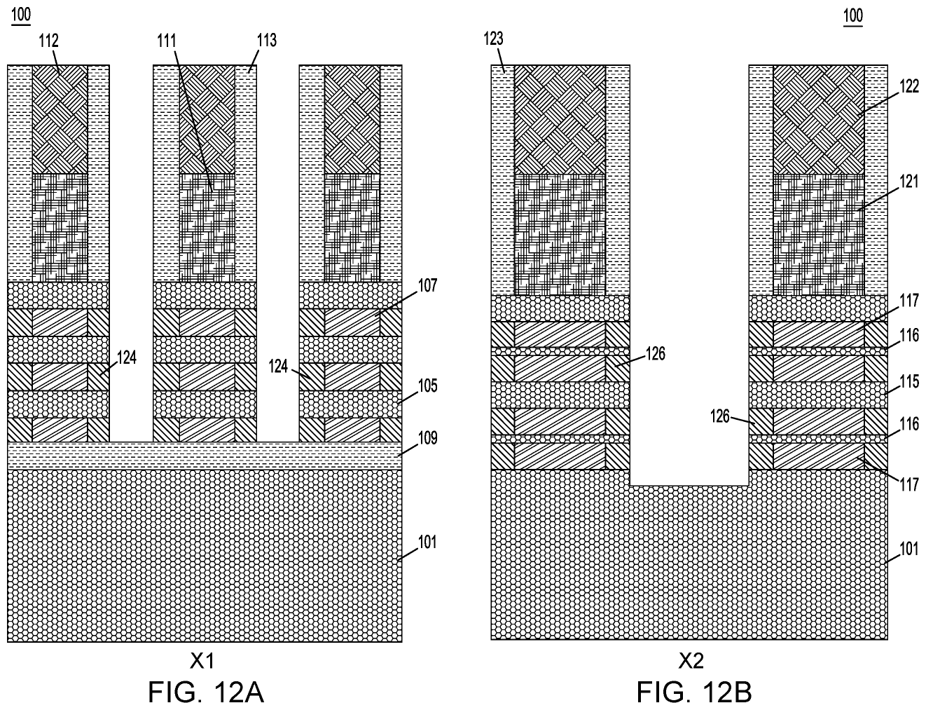

Referring to FIGS. 12A and 12B, the inner spacer dielectric material 114 in the SG and EG device regions in isotropically etched back using, for example, an isotropic etch back process such as, for example, RIE to form inner spacers 124 in the SG device region and inner spacers 126 in the EG device region. The inner spacers 124 in the SG device region may have the same or similar sizes as the inner spacers in the EG device region. As can be seen in FIG. 12A, in the SG device region, the inner spacers 124 are alternately stacked with end portions of the channel layers 105 between adjacent inner spacers 124. As can be seen in FIG. 12B, in the EG device region, stacked pairs of inner spacers 126 include an end portion of a semiconductor layer 116 between respective inner spacers 126 of a stacked pair. End portions of an EG region channel layer 115 are positioned between two stacked pairs of the inner spacers 126.

Referring to FIG. 13A, in the SG device region, source/drain regions 130-1 and 130-2 are grown from the sides of the channel layers 105. Side surfaces of respective ones of the channel layers 105 and inner spacers 124 contact a side surface at least one adjacent source/drain region 130-1 and/or 130-2. The top surfaces of the source/drain regions 130 are above the top surfaces of uppermost ones of the channel layers 105. Referring to FIG. 13B, in the EG device region, epitaxial source/drain region 130-3 is grown from the sides of the EG region channel layers 115 and semiconductor layers 116. In addition, growth of the source/drain region 130-3 also occurs from within the recessed portion 125 of the semiconductor substrate 101. As can be seen, the source/drain region 130-3 contacts the exposed portion of the semiconductor substrate 101. In addition, side surfaces of respective ones of the EG region channel layers 115, semiconductor layers 116 and inner spacers 126 contact a side surface the source/drain region 130-3. The top surface of the source/drain region 130-3 is above the top surfaces of uppermost ones of the EG region channel layers 115. The source/drain region 130-3 has a larger area (e.g., larger width (left-right direction in FIGS. 13A and 13B) than that of the source/drain regions 130-1 and 130-2.

Although the source/drain regions 130-1 and 130-2 in the SD device region have a smaller area than the source/drain region 130-3 in the EG device region, the source/drain regions 130 all grow to the same or similar heights (e.g., vertical height in FIGS. 13A and 13B). The growth to the same or similar heights is due to, for example, the BDI layer 109 reducing the rate of epitaxial growth in the SG device region, and the exposed portion of the semiconductor substrate 101 (e.g., recessed portion 125) increasing the rate of epitaxial growth in the EG device region.

According to a non-limiting embodiment of the present invention, the conditions of the epitaxial growth process for the epitaxial source/drain regions 130 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr—about 300 Torr. In the case of n-type FETS (nFETs), the source/drain regions 130 can comprise silicon doped with n-type dopants including, for example, phosphorus (P), arsenic (As) and antimony (Sb). In the case of p-type FETS (pFETs), the source/drain regions 130 can comprise silicon doped with p-type dopants including, for example, boron (B), boron fluoride (BF₂), gallium (Ga), indium (In), and thallium (Tl).

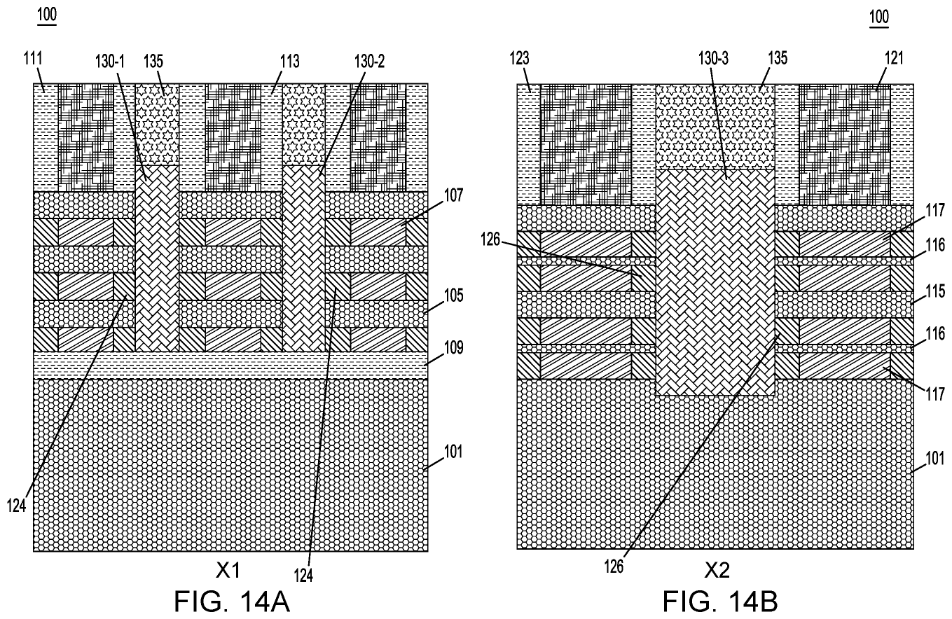

Referring to FIGS. 14A and 14B, an inter-layer dielectric (ILD) layer 135 is deposited to fill in portions on and around the source/drain regions 130 in the SG and EG device regions. The ILD layer 135 is deposited using deposition techniques such as, for example, CVD, PECVD, RFCVD, PVD, ALD, MBD, PLD, and/or LSMCD, followed by a planarization process, such as, chemical mechanical planarization (CMP) to remove excess portions of the ILD layer 135 deposited on top of the hardmask layers 112/122 and gate spacers 113/123, and to remove the hardmask layers 112/122 and portions of the gate spacers 113/123 to expose the dummy gate portions 111/121. The ILD layer 135 may comprise, for example, SiOₓ, SiOC, SiOCN or some other dielectric.

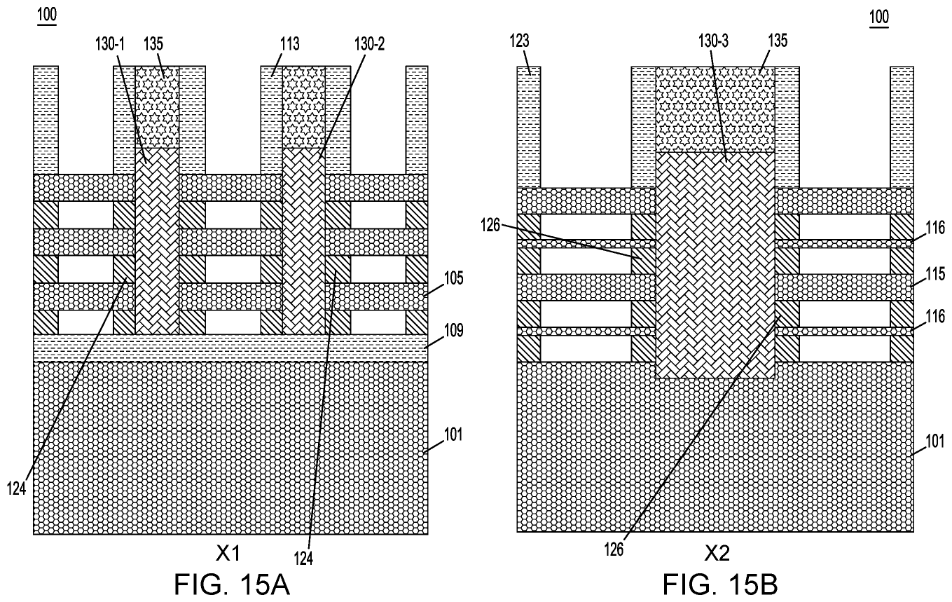

Referring to FIGS. 15A and 15B, the dummy gate portions 111/121 are selectively removed to create vacant areas where gate structures will be formed in place of the dummy gate portions 111/121. The selective removal can be performed using, for example, hot ammonia to remove a-Si. In addition, the sacrificial layers 107 are selectively removed from the SG device region to create vacant areas where gate structures will be formed in place of the sacrificial layers 107. The EG region sacrificial layers 117 are selectively removed from the EG device region to create vacant areas where gate structures will be formed in place of the EG region sacrificial layers 117. The sacrificial layers 107 are selectively removed with respect to the channel layers 105, and the EG region sacrificial layers 117 are selectively removed with respect to the EG region channel layers 115 and semiconductor layers 116. The selective removal can be performed using, for example, a dry HCl etch.

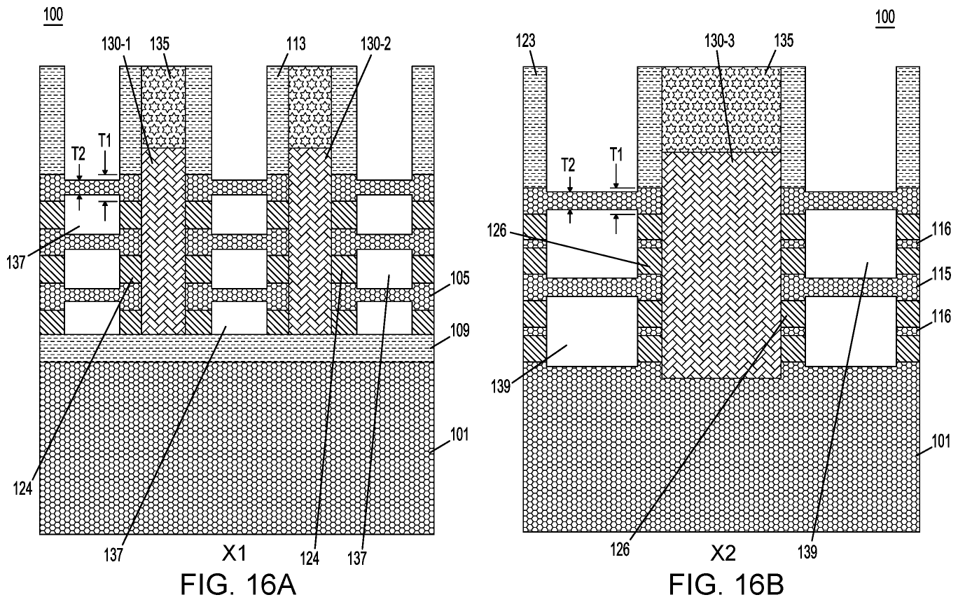

Referring to FIG. 16A, the channel layers 105 in the SG region are trimmed in an etching process to reduce the thickness (e.g., vertical thickness in FIG. 16A) of the channel layers 105 between end portions of the channel layers 105. As can be seen the end portions of the channel layers 105 have a thickness of T1 and the middle portions of channel layers 105, between the end portions, have a reduced thickness of T2. The trimming of the middle portions of channel layers 105 results in vacant portions 137. Referring to FIG. 16B, the EG region channel layers 115 in the EG region are trimmed in an etching process to reduce the thickness (e.g., vertical thickness in FIG. 16B) of the EG region channel layers 115 between end portions of the EG region channel layers 115. As can be seen the end portions of the EG region channel layers 115 have a thickness of T1 and the middle portions of EG region channel layers 115, between the end portions, have a reduced thickness of T2. As shown in FIG. 16B, the etching process removes the middle portions of the thinner semiconductor layers 116 between the end portions of the semiconductor layers 116 disposed between the inner spacers 126 of the previously described pairs of inner spacers 126. The removal of the middle portions of the thinner semiconductor layers 116 and the trimming of the middle portions of EG region channel layers 115 results in vacant portions 139. As can be seen in FIG. 16B, as part of the trimming process, exposed portions of the top surface of the semiconductor substrate 101 may be removed to recess portions of the semiconductor substrate 101. The etching process to perform the trimming of the middle portions of the channel layers 105 and EG region channel layers 115 and the removal of the middle portions of the semiconductor layers 116 includes, for example, performing a vapor phase HCl etching process, an atomic layer etching process using H₂ and NH₃ or an inter-layer (IL) process that is a well-controlled oxidation process combined with a well-controlled HF etching process, or any other process permitting well-controlled removal of the material of the channel semiconductor material layers.

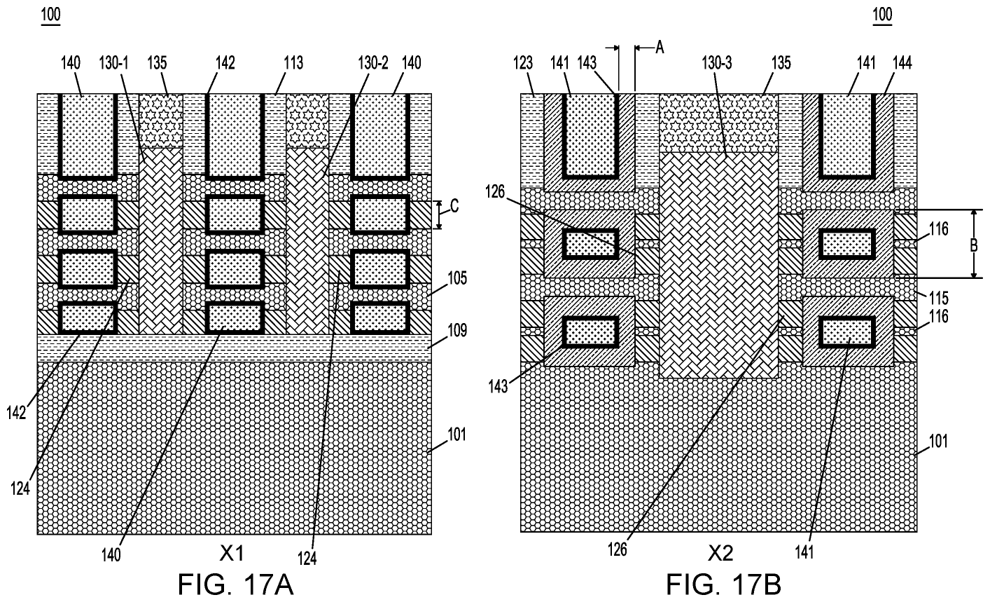

Referring to FIG. 17A, following removal of the dummy gate portions 111 and sacrificial layers 107, and trimming of the channel layers 105 in the SG device region, the channel layers 105 are suspended, and gate structures including, for example, gate portions 140 and gate dielectric layers 142 are formed in the vacant portions left by removal of the dummy gate portions 111, and the sacrificial layers 107. In illustrative embodiments, in the SG device region, each gate structure includes a single gate dielectric layer 142 disposed around all sides or a plurality of sides of a gate portion 140. In some embodiments, an optional relatively thinner (e.g., about 0.5 nm-about 1 nm) inter-layer (e.g., silicon oxide) can be deposited (not shown) prior to gate dielectric layer 142 deposition. Referring to FIG. 17B, following removal of the dummy gate portions 121, EG region sacrificial layers 117 and middle portions of the semiconductor layers 116, and trimming of the EG region channel layers 115 in the EG device region, the EG region channel layers 115 are suspended, and gate structures including, for example, gate portions 141 and gate dielectric layers 143 and 144 are formed in the vacant portions left by removal of the dummy gate portions 111, the semiconductor layers 116 and the EG region sacrificial layers 117. In illustrative embodiments, in the EG device region, each gate structure includes a two gate dielectric layers 143 and 144 disposed around all sides or a plurality of sides of a gate portion 141. Gate dielectric layer 144 can be a relatively thick (e.g., from about 1 nm to about 10 nm) EG dielectric (e.g., silicon oxide). As shown by the arrow A, the outer gate dielectric layer 144 is thicker (vertically and horizontally) than the inner gate dielectric layer 143. The inner gate dielectric layer has the same or a similar thickness and material to those of the gate dielectric layer 142.

The material of the gate dielectric layers 142 and 143 comprises, for example, a high-K dielectric material including, but not necessarily limited to, HfO₂ (hafnium oxide), HfZrO₂ (hafnium zirconium oxide), HfAlOₓ (hafnium aluminum oxide), HfLaOₓ (hafnium lanthanum oxide). Examples of other high-k materials that may be used as the gate dielectric layers 142 and 143 include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The material of the gate dielectric layer 144 includes, for example, a combination of SiOₓ and a high-K dielectric material noted herein above.

According to an embodiment, the gate portions 140 and 141 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer 142 or 143. The gate portions 140 and 141 can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer. It should be appreciated that various other materials may be used for the gate portions 140 and 141 as desired.

As can be understood from FIGS. 17A and 17B, the gate structures in SG device region each comprise a gate portion 140 and a single gate dielectric layer 142 around the gate portion 140, and the gate structures in the EG device region each comprise a gate portion 141 and two gate dielectric layers 143 and 144 around the gate portion. The gate lengths of the respective gate portions 140 are less than the gate lengths of the respective gate portions 141. Gate lengths refers to the widths of the gate portions 140 and 141 in FIGS. 17A and 17B. In some embodiments, the gate lengths of the respective gate portions 140 may be the same as the gate lengths of the respective gate portions 141.

Respective stacked inner spacer structures are disposed on respective sides of the respective ones of the gate structures in the EG device region. Each of the respective stacked inner spacer structures comprises a first inner spacer 126 and a second inner spacer 126 vertically stacked, with a remaining portion of a semiconductor layer 116 between the first inner spacer 126 and second inner spacer 126.

As can be seen in FIGS. 17A and 17B, each of the channel layers 105 and each of the EG device channel layers 115 have a greater thickness than the remaining portions of the semiconductor layers 116. In addition, the BDI layer 109 is in the SG device region and located between the lowermost gate structures in the SG device region and the semiconductor substrate 101. The BDI layer 109 is also located between the bottom surfaces of the epitaxial source/drain regions 130-1 and 130-2 and the top surface of the semiconductor substrate 101. The BDI layer is omitted from the EG device region, such that the lowermost gate structures and epitaxial source/drain region 130-3 in the EG device region are disposed directly on and contact the semiconductor substrate 101.

The channel layers 105 in the SG device region and the EG region channel layers 115 have a varying thickness along a direction parallel to a top surface of the semiconductor substrate 101. A vertical distance between the respective gate portions 140 is less than a vertical distance between respective gate portions 141. A horizontal distance between the respective gate portions 140 is less than a horizontal distance between respective gate portions 141. In addition, the space between the EG device channel layers 115 (Tₛᵤₛ) as shown by arrow B in FIG. 17B is greater than the space between the channel layers 105 in the SG device region as shown by arrow C in FIG. 17A.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming SG and EG nanosheet transistors. The embodiments advantageously provide an SG nanosheet transistor including a BDI layer and an EG nanosheet transistor without a BDI layer. As an additional advantage, illustrative embodiments provide structures and techniques for forming EG nanosheet transistors with a semiconductor layer between two stacked inner spacers, where the semiconductor layer between the two inner spacers is thinner than the channel layers.

It should be understood that the various layers, structures, and regions shown in the figures are schematic illustrations that are not drawn to scale. In addition, for case of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first nanosheet transistor disposed on a semiconductor substrate, the first nanosheet transistor comprising a plurality of first gate structures; and
a second nanosheet transistor disposed on the semiconductor substrate, the second nanosheet transistor comprising a plurality of second gate structures; and
respective stacked spacer structures disposed on respective sides of respective ones of the plurality of second gate structures, wherein each of the respective stacked spacer structures comprises a first spacer and a second spacer;
wherein respective ones of the plurality of first gate structures comprise a first nanosheet gate portion and a gate dielectric layer around the first nanosheet gate portion; and
wherein the respective ones of the plurality of second gate structures comprise a second nanosheet gate portion and at least two gate dielectric layers around the second nanosheet gate portion.

2. The semiconductor device of claim 1, wherein each of the respective stacked spacer structures further comprise a semiconductor layer disposed between the first spacer and the second spacer.

3. The semiconductor device of claim 2, wherein the second nanosheet transistor further comprises a plurality of channel regions alternately stacked with the plurality of second gate structures, and respective ones of the plurality of channel regions have a greater thickness than the semiconductor layer of each of the respective stacked spacer structures.

4. The semiconductor device of claim 1, wherein the first spacer and the second spacer are stacked vertically with respect to a top surface of the semiconductor substrate.

5. The semiconductor device of claim 1, wherein gate lengths of respective first nanosheet gate portions of the plurality of first gate structures are less than gate lengths of respective second nanosheet gate portions of the plurality of second gate structures.

6. The semiconductor device of claim 1, further comprising a dielectric layer between the first nanosheet transistor and the semiconductor substrate.

7. The semiconductor device of claim 6, wherein the second nanosheet transistor is disposed on the semiconductor substrate without the dielectric layer between the second nanosheet transistor and the semiconductor substrate.

8. The semiconductor device of claim 1, wherein the first nanosheet transistor further comprises a plurality of channel regions alternately stacked with the plurality of first gate structures, and respective ones of the plurality of channel regions have a varying thickness along a direction parallel to a top surface of the semiconductor substrate.

9. The semiconductor device of claim 1, wherein the second nanosheet transistor further comprises a plurality of channel regions alternately stacked with the plurality of second gate structures, and respective ones of the plurality of channel regions have a varying thickness along a direction parallel to a top surface of the semiconductor substrate.

10. The semiconductor device of claim 1, wherein a distance between the first nanosheet gate portions of the respective ones of the plurality of first gate structures is less than a distance between the second nanosheet gate portions of the respective ones of the plurality of second gate structures.

11. The semiconductor device of claim 1, wherein a first gate dielectric layer of the at least two gate dielectric layers has a different thickness from a second gate dielectric layer of the at least two gate dielectric layers.

12. A semiconductor device comprising:
a first nanosheet structure comprising a first plurality of gate structures alternately stacked with a first plurality of channel layers;
a second nanosheet structure comprising a second plurality of gate structures alternately stacked with a second plurality of channel layers; and
respective stacked spacer structures disposed on respective sides of respective ones of the second plurality of gate structures, wherein each of the respective stacked spacer structures comprises a first spacer and a second spacer;
wherein respective ones of the first plurality of gate structures comprise a first nanosheet gate portion and a gate dielectric layer around the first nanosheet gate portion; and
wherein the respective ones of the second plurality of gate structures comprise a second nanosheet gate portion and at least two gate dielectric layers around the second nanosheet gate portion.

13. The semiconductor device of claim 12, wherein each of the respective stacked spacer structures further comprise a semiconductor layer disposed between the first spacer and the second spacer.

14. The semiconductor device of claim 13, wherein respective ones of the second plurality of channel layers have a greater thickness than the semiconductor layer of each of the respective stacked spacer structures.

15. The semiconductor device of claim 12, wherein the second spacer is stacked on top of the first spacer.

16. The semiconductor device of claim 12, wherein gate lengths of respective first nanosheet gate portions of the first plurality of gate structures are less than gate lengths of respective second nanosheet gate portions of the second plurality of gate structures.

17. The semiconductor device of claim 12, wherein respective ones of the second plurality of channel layers have a varying thickness.

18. A semiconductor device comprising:
a first nanosheet transistor disposed on a semiconductor substrate, the first nanosheet transistor comprising a first plurality of stacked gate portions, a gate dielectric layer around respective ones of the first plurality of stacked gate portions and a first source/drain region disposed on a side of the first plurality of stacked gate portions; and
a second nanosheet transistor disposed on the semiconductor substrate, the second nanosheet transistor comprising a second plurality of stacked gate portions, at least two gate dielectric layers around respective ones of the second plurality of stacked gate portions and a second source/drain region disposed on a side of the second plurality of stacked gate portions; and
respective stacked spacer structures disposed on respective sides of the respective ones of the second plurality of stacked gate portions between the second source/drain region and the respective ones of the second plurality of stacked gate portions, wherein each of the respective stacked spacer structures comprises a first spacer and a second spacer.

19. The semiconductor device of claim 18, wherein gate lengths of the respective ones of the first plurality of stacked gate portions are less than gate lengths of the respective ones of the second plurality of stacked gate portions.

20. The semiconductor device of claim 18, wherein a portion of the second source/drain region is disposed in a recessed portion of the semiconductor substrate.
